(19) United States
(12) Patent Application Publication
(10) Pub. No.: US 2026/0128580 A1
(43) Pub. Date: May 7, 2026

(54) DYNAMIC CURRENT PROTECTION FOR SERVER LOADS

(71) Applicant: LENOVO GLOBAL TECHNOLOGY (UNITED STATES) INC., MORRISVILLE, NC (US)

(72) Inventors: ROBERT R. WOLFORD, STRONGSVILLE, OH (US); WILLIAM J. WALKER, CYPRESS, TX (US)

(21) Appl. No.: 18/936,807

(22) Filed: Nov. 4, 2024

(51) Int. Cl. H02H 1/00; H02H 3/08

(52) U.S. Cl. CPC H02H 1/0092; H02H 3/08

(57) ABSTRACT

Methods, apparatus, and products for dynamic current protection for server loads include multiple computer components, a programmable eFuse (electronic fuse) coupled to the multiple computer components, and a BMC (baseboard management controller) coupled to the programmable eFuse. The BMC is configured to: during a startup procedure, program one or more limits of the eFuse based on configuration data associated with each of the plurality of computer components, enable, prior to completing the startup procedure, the programmable eFuse with the one or more limits, and perform, while the eFuse is enabled, a test on the plurality of computer components using the eFuse.

### BACKGROUND

The present disclosure relates to methods, apparatus, and products for dynamic current protection for server loads.

### SUMMARY

Methods, apparatus, and products for dynamic current protection for server loads according to various embodiments are disclosed in this specification. In accordance with one aspect of the present disclosure, a method of dynamic current protection for server loads includes, during a startup procedure of a system that includes a plurality of computer components, programming one or more limits of a programmable eFuse (electronic fuse) based on configuration data associated with each of the plurality of computer components; and enabling, prior to completing the startup procedure of the system, the programmable eFuse with the one or more limits; and performing, while the eFuse is enabled, a test on the plurality of computer components using the eFuse.

In accordance with another aspect of the present disclosure, dynamic current protection for server loads may include an apparatus including multiple computer components, a programmable eFuse (electronic fuse) coupled to the multiple computer components, and a BMC (baseboard management controller) coupled to the programmable eFuse. The BMC is configured to: during a startup procedure, program one or more limits of the eFuse based on configuration data associated with each of the plurality of computer components, enable, prior to completing the startup procedure, the programmable eFuse with the one or more limits, and perform, while the eFuse is enabled, a test on the plurality of computer components using the eFuse.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example block diagram of a system for dynamic current protection for server loads in accordance with embodiments of the present disclosure.

FIG. 2 shows an example block diagram of another system for dynamic current protection for server loads in accordance with embodiments of the present disclosure.

FIG. 3 shows an example lookup table for dynamic current protection for server loads in accordance with embodiments of the present disclosure.

FIG. 4 is a flowchart of an example method of dynamic current protection for server loads according to some embodiments of the present disclosure.

FIG. 5 is a flowchart of another example method of dynamic current protection for server loads according to some embodiments of the present disclosure.

### DETAILED DESCRIPTION

DIMMs (dual in-line memory modules) are a popular type of memory module in computer systems that include RAM (random access memory) and pins that connect the RAM to a computer's motherboard. Computers often contain multiple DIMMs at once, and the DIMMs are typically powered by 12V of DC (direct current) power. The DIMMs may be protected electrically in a number of different of ways. One method of protecting the DIMMs electrically is by relying on power supply over current protection (OCP), which is a safety feature of some power supplies that stops the output of power if the output current exceeds a specified value or limit and becomes larger than expected. However, because DIMMs do not require a lot of power or current, a DIMM can become damaged well before an OCP limit of a power supply is exceeded. A DIMM may become damaged when it experiences more current than it is designed to handle. For example, a DIMM that receives too much current may experience a soft short, a smoke event, a thermal event, or even a flame event. A soft-short is defined as a short of 10 s of mOhms (mΩ) to 1 ohm between the bulk voltage rail (e.g. 12V) and GND (ground). The resistance of the short is high enough to prevent the current from tripping the power supply OCP, but low enough to allow high current to flow to a device and cause physical damage and a smoke/burn/flame event in the device or the traces, vias, and connectors that route power to the device. By relying on only the power supply's OCP, the DIMMs are not fully protected from such damage.

Another method of protecting the DIMMs is using a fuse or an eFuse that is coupled to the DIMMs. However, in conventional methods, the eFuse is statically set for the worst-case scenario and left unchanged, independent of changes in the system or DIMM configuration. For example, such a worst-case scenario may consider the greatest potential number of installed DIMMs that are working under the heaviest potential workload. In such an example, if fewer DIMMs are used and/or a lighter workload is executing, the DIMMs could develop a soft short and become damaged before the coupled fuse ever trips.

The embodiments of the present disclosure describe a more precise method of providing current protection for server DIMMs (and other computer components) that will provide for increased assurance that smoking, burning, or open-flame incidents (or other similar damage) will not occur on DIMMs due to a critical power problem. The embodiments of the present disclosure describe a system with a programmable eFuse that provides custom-tailored protection over the DIMMs by dynamically programming the eFuse (before the system is powered on) according to an amount (e.g., number) and/or size of the DIMMs that are being used within the system. Such a method of protection may also be applied to other computer components, as described in the various embodiments of the present disclosure.

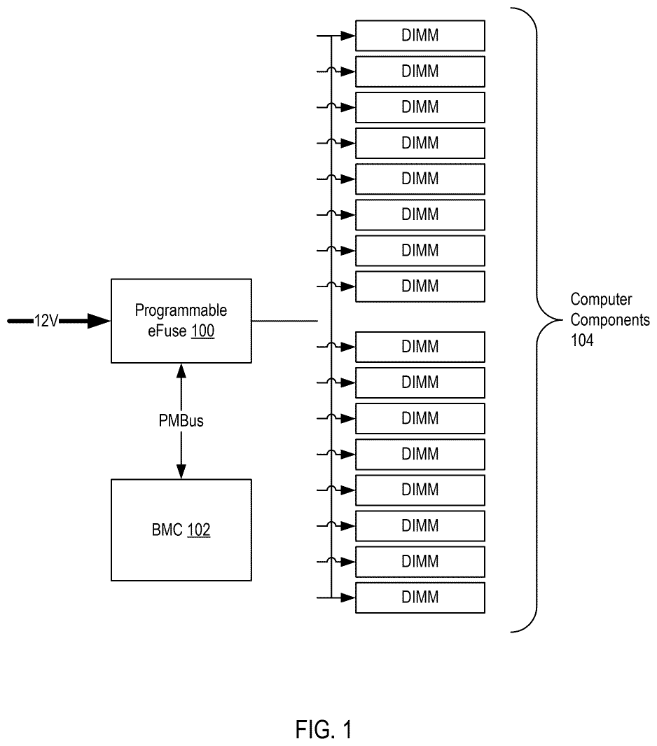

Exemplary methods, apparatus, and products for dynamic current protection for server loads in accordance with the present disclosure are described with reference to the accompanying drawings, beginning with FIG. 1. FIG. 1 sets forth an example block diagram of a system for dynamic current protection for server loads in accordance with embodiments of the present disclosure. FIG. 1 shows a BMC (baseboard management controller) 102, a programmable eFuse 100, and multiple computer components 104 coupled to the eFuse 100.

The example BMC 102 is communicatively coupled to the programmable eFuse 100 via a PMBus (Power Management Bus), allowing the BMC to program the eFuse by setting or updating one or more limits of the eFuse. In a programmable eFuse, many aspects of the eFuse operation, including current limits, can be programmed over a PMBus. A BMC is a specialized service processor or controller that may be used for remote monitoring and management of a computing system, allowing admins to perform maintenance tasks or other management functions on a computing system without having to physically connect to the computing system. The BMC 102 can be accessed and managed through a management module (not shown in FIG. 1).

The example computer components 104 of FIG. 1 consist of multiple DIMMs (however the computer components may be other types of computer components, as described in other embodiments of the present disclosure. The example programmable eFuse 100 is coupled to each of the computer components 104 to deliver power to computer components. In the example embodiment of FIG. 1, the DIMMs each receive 12V of power from the power supply via the programmable eFuse 100. For example, the bold 12V arrow included within FIG. 1 indicates the 12V power received from the power supply, which the eFuse then distributes to the coupled DIMMs. In this way, the eFuse 100 is configured to provide current protection to the coupled computer components 104.

In order to dynamically protect the computer components 104 from power-related events, the programmable eFuse must be programmed according to the configuration of the computer components. Such programming begins each time standby power is initially applied to the server. This typically occurs when the AC line or power cord from the power supply is plugged in, e.g., to mains power or a rack bus line. At this point the system is off (e.g., power may be absent from a main power rail) but the BMC 102 may be in an initializing state using power obtained from a separate power rail sourced from the AC line. After the BMC is done initializing, the BMC 102 may check the DIMM inventory of the computer components 104. For example, the BMC 102 may check the configuration of the computer components by reading the SPD (serial presence detect) data to check for the presence, type, size, and number of DIMMs.

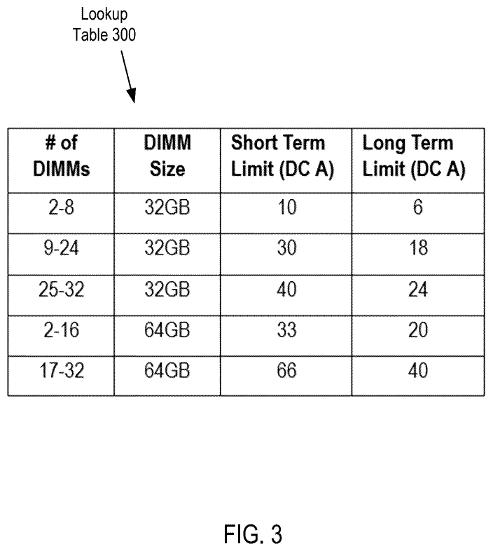

Once the DIMM inventory is complete, the BMC 102 checks the determined installed DIMM topology against a stored table that defines the eFuse current limit levels for all possible supported DIMM combinations. For further explanation, FIG. 3 sets forth an example lookup table 300. The values stored in the lookup table 300 are created based on known current consumption values for the various types of DIMMs supported in the server. Each row of the table is mutually exclusive, and once the BMC finds the table row that matches the determined DIMM topology, the BMC may then identify the current limits to program into the eFuse. For example, when referencing the lookup table 300 of FIG. 3, if BMC 102 determines that the DIMM configuration of the computer components 104 includes 16 64 GB DIMMs, then the BMC will identify the fourth row as matching the determined DIMM topology and program the eFuse with a short term limit of 33 A and a long term limit of 20 A, according to the lookup table. The example lookup table 300 is only one possible example of entries included within the table, and the lookup table may include any combination of entries or values, depending on the system.

Returning to FIG. 1, the BMC 102 is configured to, using the values selected from the lookup table, program short term and long term current limits into the eFuse that is protecting the downstream DIMMs. At this point, the eFuse current limit has been optimized specifically for the size, type, and number of DIMMs currently installed in the server. In some embodiments, the programming of the eFuse may include reprogramming the eFuse by changing the limits of the eFuse based on a change in the configuration of the computer components. Because the programming of the eFuse occurs each time AC power is delivered to the power supply of the system, any change in computer component configuration will result in an updated programming of the eFuse to provide proper current protection to the components.

After programming the eFuse, the BMC is configured to enable the eFuse by allowing the eFuse to receive the 12V of power from the power supply, and thus provide power to the coupled computer components. In an embodiment, only the programmed eFuse is enabled while the rest of the system is still off. At this point, the eFuse current limits are optimized for the number and type of DIMMs installed. If the eFuse current limit protection trips, such an eFuse trip is an indication that there is a power problem at the onset somewhere in the power delivery path between the eFuse and the DIMMs (e.g. a PCB, a connector, a DIMM module, and the like). If the eFuse current limit trips, the BMC is configured to prevent the system from being powered on and an error is written into the system error log (SEL). Such an embodiment provides a “pre-launch” check of the DIMMs before the entire server is turned on. If the DIMM eFuse current limit did not trip, then the BMC is configured to disable the programmable eFuse 100 and then permit the entire system to be powered on, following the normal power-on sequence. With the above algorithm, the BMC 102 uses optimized current limit checking of the DIMMs, based on knowledge of the actual DIMM configuration, and at time 0 (before the system is allowed to fully power on), to provide proper current protection to the DIMMs both at system startup and also at runtime (after the server is fully powered on).

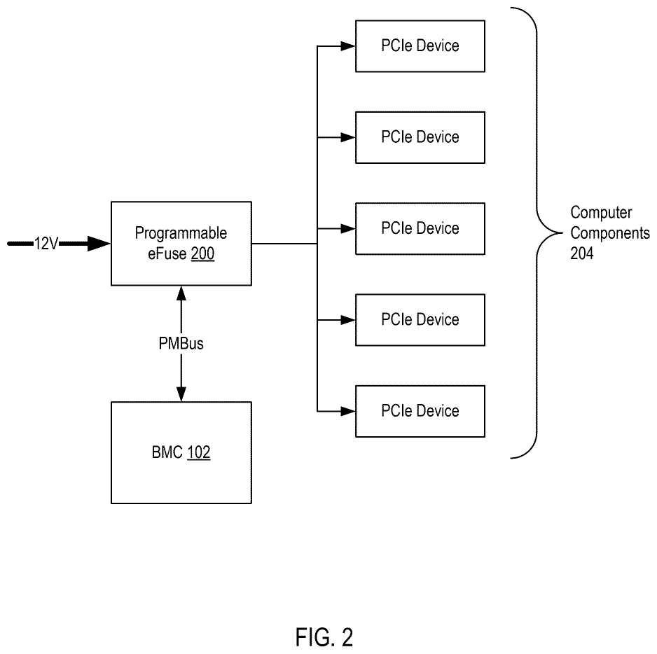

For further explanation, FIG. 2 sets forth an example block diagram of another system for dynamic current protection for server loads in accordance with embodiments of the present disclosure. The system of FIG. 2 differs from the system of FIG. 1 in that the system of FIG. 2 has the programmable eFuse 200 coupled to multiple PCIe devices as the computer components 204. In such an embodiment, the PCIe devices are protected in the same way as the DIMMs of FIG. 1. One distinction between how the PCIe devices are protected is in the configuration data that is determined and for basing the eFuse limits on. For example, rather than a DIMM size and amount, the eFuse 200 may instead have its limits selected based on known power consumption values associated with the PCIe devices, along with the number of devices coupled to the eFuse.

In some embodiments, the BMC is coupled to multiple eFuses that each protect a group of computer components, where the BMC is configured to uniquely program each eFuse according to the embodiments of the present disclosure. For example, in a system, one eFuse may protect a group of DIMMs, a second eFuse may protect a second group of DIMMs, and a third eFuse may protect a group of PCIe devices. It will be understood that other types of computer components may also be provided current protection according to the embodiments of the present disclosure.

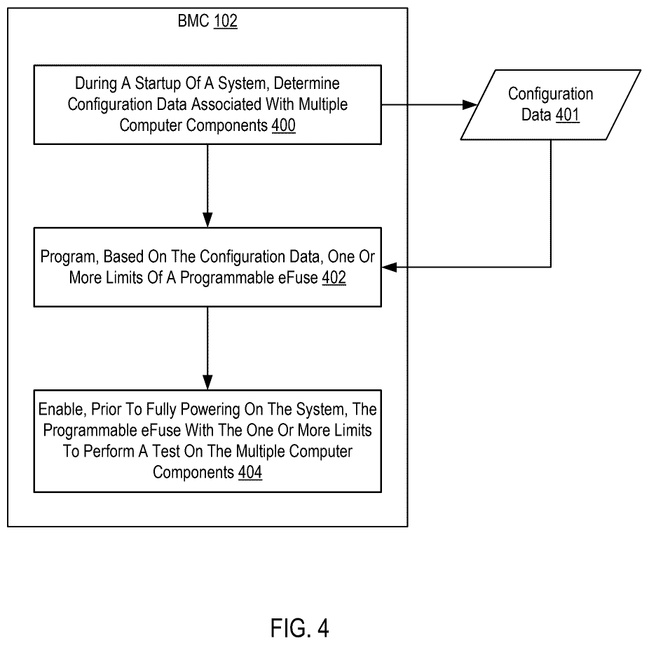

For further explanation, FIG. 4 sets forth a flowchart of an example method of dynamic current protection for server loads according to some embodiments of the present disclosure. The method of FIG. 4 includes determining 400 configuration data associated with multiple computer components. Determining 400 configuration data associated with multiple computer components may be carried out by BMC 102 during a startup of the system and before the entire system is powered on. Specifically, the determination (as well as the remaining steps of FIG. 4) may occur while the system is off, and only the BMC and BMC subsystems are powered on (such as by the 12V auxiliary rail) and running. In some embodiments, the BMC subsystems include a circuit within each of the DIMMs that is powered by the auxiliary 12V rail that is communicatively coupled to the BMC, allowing for the BMC to determine the inventory of the DIMMs while the system is powered off.

The determination 400 made by BMC 102 includes receiving configuration data 401 associated with the computer components. For example, the BMC 102 is configured to communicate with the computer components in order to take inventory of the amount and size (and other types of information) describing the computer components coupled to the programmable eFuse. In an embodiment where the computer components are DIMMs, the configuration data includes the size of each DIMM coupled to the programmable eFuse, and the amount of each size of DIMM coupled to the eFuse. In other embodiments where the computing components are another type of computer component (such as PCIe devices, or some other type of computer component), the configuration data 401 may include other types of information associated with the computer components.

The method of FIG. 4 further includes programming 402, based on the configuration data, one or more limits of a programmable eFuse. Programming 402, based on the configuration data 401, the one or more limits of a programmable eFuse may be carried out by BMC 102 selecting one or more limits (current thresholds that determine when the eFuse trips and ceases delivering power to the computing components) based on the determined configuration of the computer components. In one embodiment, the selected limits include a short-term limit and a long-term limit. In one example, the short-term limit value is based on the average current measurement experienced by the eFuse on the order of several milliseconds (5 ms, 10 ms, 15 ms, etc.) while the long-term limit may measure the average measurement of current experienced by the eFuse on the order of tens of seconds (10 s, 20 s, 30 s, etc.). By having two different limits programmed for the eFuse, the computer components are better protected from short spikes of increased current, as well as steadily climbing increases in current.

The method of FIG. 4 further includes enabling 404, prior to fully powering on the system, the programmable eFuse with the one or more limits to perform a test on the multiple computer components. Enabling 404 the programmable eFuse with the one or more limits may be carried out by BMC 102 by allowing power to be delivered to the eFuse with the eFuse enabled, which in turn delivers power to each of the downstream coupled computer components (without turning on the rest of the system) to perform a test on the multiple computer components prior to fully powering on the system. Such a test may include monitoring the eFuse to determine whether or not the eFuse trips during the test while the computer components coupled to the eFuse are being delivered power. By testing the computer components prior to turning on the system, the eFuse-coupled computer components are provided with a more secure and reliable form of protection that is dynamically selected according to the configuration of the computer components.

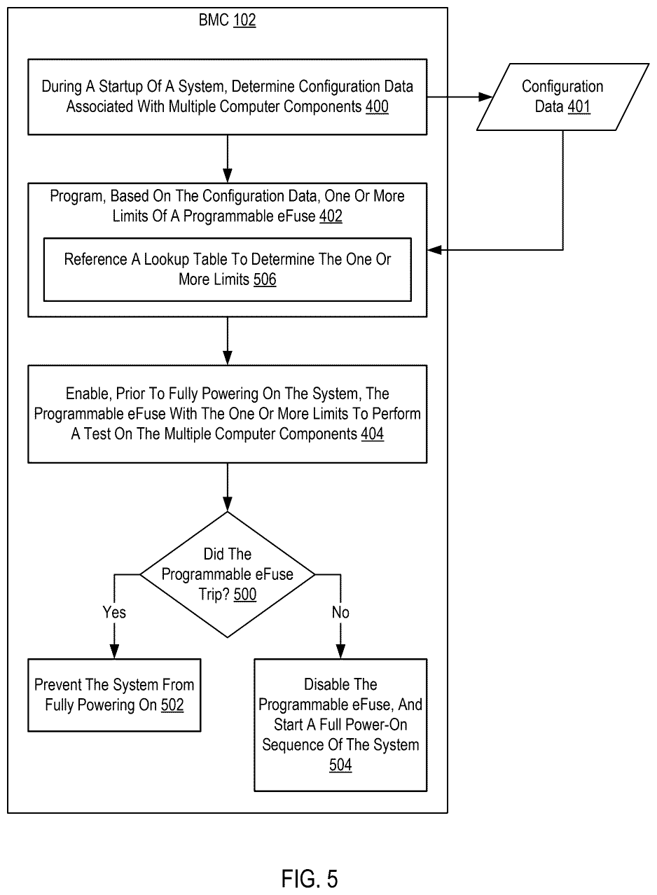

For further explanation, FIG. 5 sets forth a flowchart of another example method of dynamic current protection for server loads according to some embodiments of the present disclosure. The method of FIG. 5 differs from the method of FIG. 4 in that the method of FIG. 5 further includes determining 500 whether the programmable eFuse tripped. Determining 500 whether the programmable eFuse tripped may be carried out by BMC 102 responsive to enabling 404 the eFuse before turning on the rest of the system. Determining 500 whether the programmable eFuse tripped includes monitoring the eFuse while power is being delivered to the eFuse (and, in turn, the coupled computer components). The monitoring may be performed for a preset amount of time (programmed automatically, or manually set by an administrator). If one of the coupled computer components has a short circuit (even a soft short), then it will trip the eFuse by exceeding one or more of the programmed limits of the eFuse.

The method of FIG. 5 further includes, if the programmable eFuse did trip, preventing 502 the system from fully powering on. Preventing 502 the system from fully powering on may be carried out by BMC 102 storing an error in an error log that indicates the eFuse trip and prevents the system from subsequently powering on. For example, if, during the preset amount of time while the system is off and the eFuse is enabled, a DIMM coupled to the eFuse develops a soft short and trips the eFuse, the BMC will store an error in the error log indicating the tripped eFuse (which in turn indicates a power even occurred within a coupled computer component) and will lockout the system to prevent it from powering on. In such an example, a user may be alerted by the error that the system is locked out due to a computer component that has a short.

The method of FIG. 5 further includes, if the programmable eFuse did not trip, disabling 504 the programmable eFuse, and starting a full power-on sequence of the system. Disabling 504 the programmable eFuse and starting a full power-on sequence of the system may be carried out by BMC 102 turning the eFuse back off (so that power is no longer being delivered to the eFuse and thus the computer components) and then allowing the system to perform its normal power-on sequence. By turning back off the eFuse, the system is then allowed to carry out its normal power-on sequence, which includes powering back on the eFuse with its programmed limits in place.

The method of FIG. 5 further includes, as part of programming 402, based on the configuration data, one or more limits of a programmable eFuse, referencing 506 a lookup table to determine the one or more limits. Referencing 506 a lookup table to determine the one or more limits may be carried out by BMC 102 referencing a lookup table (such as a table similar to the lookup table of FIG. 3) and identifying an entry with configuration data that matches the configuration data 401 determined that describes the configuration of the computer components coupled to the eFuse. In such an embodiment, the one or more limits of the eFuse are included in the identified entry that correspond to the configuration data, and the BMC uses the included limits within the entry to program the eFuse accordingly.

In view of the explanations set forth above, readers will recognize that the benefits of dynamic current protection for server loads according to embodiments of the present disclosure include:
Providing more sensitive protection against overcurrent events (and thereby reducing the chance of a smoke, burn, or open flame event) by dynamically calculating the current limit protection levels that get set for server DIMM (or other components) eFuses.

The flowchart and block diagrams in the Figures illustrate the architecture, functionality, and operation of possible implementations of systems, methods, and apparatus according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A method of dynamic current protection, the method comprising:
during an initial startup procedure of a system that includes a plurality of computer components, programming one or more limits of a programmable eFuse (electronic fuse) based on configuration data associated with each of the plurality of computer components; and
enabling, prior to completing the initial startup procedure of the system, the programmable eFuse with the one or more limits; and
performing, while the eFuse is enabled, a test on the plurality of computer components using the eFuse.

2. The method of claim 1, further comprising preventing the system from completing the initial startup procedure or from executing a full startup procedure based on a determination that the programmable eFuse has tripped during the performing of the test on the plurality of computer components using the eFuse.

3. The method of claim 1, further comprising, based on a determination that the programmable eFuse did not trip during the performing of the test on the plurality of computer components using the eFuse:
disabling the programmable eFuse; and
executing a full startup procedure of the system, wherein the programmable eFuse is not enabled during the full startup procedure.

4. The method of claim 1, wherein each of the plurality of computer components is a DIMM (dual in-line memory module), and wherein the configuration data includes a number of DIMMs of the plurality of computer components and a size of each of the DIMMs of the plurality of computer components.

5. The method of claim 4, wherein programming the one or more limits of the plurality of computer components includes referencing a lookup table to determine the one or more limits.

6. The method of claim 5, wherein the lookup table includes multiple entries, and wherein each entry in the lookup table identifies:
a possible DIMM configuration, including a DIMM size and a number of DIMMs; and
a corresponding one or more limits.

7. The method of claim 1, wherein the one or more limits of the programmable eFuse include a short-term limit and a long-term limit.

8. An apparatus comprising:
a plurality of computer components;
a programmable eFuse (electronic fuse) coupled to the plurality of computer components; and
a BMC (baseboard management controller) coupled to the programmable eFuse, wherein the BMC is configured to:
during an initial startup procedure, program one or more limits of the eFuse based on configuration data associated with each of the plurality of computer components;
enable, prior to completing the initial startup procedure, the programmable eFuse with the one or more limits; and
perform, while the eFuse is enabled, a test on the plurality of computer components using the eFuse.

9. The apparatus of claim 8, wherein each of the plurality of computer components is a DIMM (dual in-line memory module).

10. The apparatus of claim 9, wherein the configuration data includes a number of DIMMs of the plurality of computer components and a size of each of the DIMMs of the plurality of computer components.

11. The apparatus of claim 9, wherein programming the one or more limits of the plurality of computer components includes referencing a lookup table to determine the one or more limits.

12. The apparatus of claim 11, wherein the lookup table includes multiple entries, and wherein each entry in the lookup table identifies:
a possible DIMM configuration, including a DIMM size and a number of DIMMs; and
a corresponding one or more limits.

13. The apparatus of claim 8, wherein the plurality of computer components consists of a plurality of PCIe (dual in-line memory modules) devices.

14. The apparatus of claim 8, wherein the BMC is further configured to prevent the system from completing the initial startup procedure or from executing a full startup procedure based on a determination that the programmable eFuse has tripped during the performing of the test on the plurality of computer components using the eFuse.

15. A computer program product comprising a computer readable storage medium and computer program instructions stored therein that, when executed, are configured to:
during an initial startup procedure of a system that includes a plurality of computer components, program one or more limits of a programmable eFuse (electronic fuse) based on configuration data associated with each of the plurality of computer components; and
enable, prior to completing the initial startup procedure of the system, the programmable eFuse with the one or more limits; and
perform, while the eFuse is enabled, a test on the plurality of computer components using the eFuse.

16. The computer program product of claim 15, wherein the computer program instructions, when executed, are further configured to prevent the system from completing the initial startup procedure or from executing a full startup procedure based on a determination that the programmable eFuse has tripped during the performing of the test on the plurality of computer components using the eFuse.

17. The computer program product of claim 15, wherein the computer program instructions, when executed, are further configured to, based on a determination that the programmable eFuse did not trip during the performing of the test on the plurality of computer components using the eFuse:
disable the programmable eFuse; and
execute a full startup procedure of the system, wherein the programmable eFuse is not enabled during the full startup procedure.

18. The computer program product of claim 15, wherein each of the plurality of computer components is a DIMM (dual in-line memory module), and wherein the configuration data includes a number of DIMMs of the plurality of computer components and a size of each of the DIMMs of the plurality of computer components.

19. The computer program product of claim 15, wherein programming the one or more limits of the plurality of computer components includes referencing a lookup table to determine the one or more limits.

20. The computer program product of claim 15, wherein the one or more limits of the programmable eFuse include a short-term limit and a long-term limit.
